(19) United States
(12) Patent Application Publication
(10) Pub. No.: US 2009/0017631 A1
(43) Pub. Date: Jan. 15, 2009

(54) SELF-ALIGNED PILLAR PATTERNING USING MULTIPLE SPACER MASKS

(76) Inventor: Christopher D. Bencher, San Jose, CA (US)

Correspondence Address: APPLIED MATERIALS/BSTZ;BLAKELY SOKOLOFF TAYLOR & ZAFMAN LLP, 1279 OAKMEAD PARKWAY, SUNNYVALE, CA, 94085-4040, US

(21) Appl. No.: 12/119,836

(22) Filed: May 13, 2008

Related U.S. Application Data
(60) Provisional application No. 60/932,635, filed on Jun. 1, 2007.

(51) Int. Cl. H01L 21/311

(52) U.S. Cl. 438/703; 257/E21.249

(57) ABSTRACT

A method for fabricating a semiconductor mask is described. The image of a series of lines from a first spacer mask is first provided to a mask layer to form a patterned mask layer. The image of a series of lines from a second spacer mask is then provided to the patterned mask layer to form a pillar mask comprised of a series of pillars. The image of the series of lines from the second spacer mask is non-parallel with the series of lines from the first spacer mask.

### CROSS REFERENCE TO RELATED APPLICATIONS

This application claims the benefit of U.S. Provisional Application No. 60/932,635 filed Jun. 1, 2007, the entire contents of which are hereby incorporated by reference herein.

### BACKGROUND OF THE INVENTION

1) Field of the Invention

The invention is in the field of Semiconductor Processing.

2) Description of Related Art

For the past several decades, the scaling of features in integrated circuits has been the driving force behind an ever-growing semiconductor industry. Scaling to smaller and smaller features enables increased densities of functional units on the limited real estate of semiconductor chips. For example, shrinking transistor size allows for the incorporation of an increased number of logic and memory devices on a microprocessor, lending to the fabrication of products with increased complexity.

Scaling has not been without consequence, however. As the dimensions of the fundamental building blocks of microelectronic circuitry are reduced and as the sheer number of fundamental building blocks fabricated in a given region is increased, the constraints on the lithographic processes used to pattern these building blocks have become overwhelming. In particular, there may be a trade-off between the smallest dimension of a feature patterned in a semiconductor stack (the critical dimension) and the spacing between such features. FIGS. 1A-C illustrate cross-sectional views representing a conventional semiconductor lithographic process, in accordance with the prior art.

Referring to FIG. 1A, a photoresist layer 104 is provided above a semiconductor stack 102. A mask or reticle 106 is positioned above photoresist layer 104. A lithographic process includes exposure of photoresist layer 104 to light (hv) having a particular wavelength, as indicated by the arrows in FIG. 1A. Referring to FIG. 1B, photoresist layer 104 is subsequently developed to provide patterned photoresist layer 108 above semiconductor stack 102. That is, the portions of photoresist layer 104 that were exposed to light are now removed. The width of each feature of patterned photoresist layer 108 is depicted by the width ‘x.’ The spacing between each feature is depicted by the spacing ‘y.’ Typically, the limit for a particular lithographic process is to provide features having a critical dimension equal to the spacing between the features, i.e. x=y, as depicted in FIG. 1B.

Referring to FIG. 1C, the critical dimension (i.e. the width ‘x’) of a feature may be reduced to form patterned photoresist layer 110 above semiconductor stack 102. The critical dimension may be shrunk by over-exposing photoresist layer 104 during the lithographic step depicted in FIG. 1A or by subsequently trimming patterned photoresist layer 108 from FIG. 1B. However, this reduction in critical dimension comes at the expense of an increased spacing between features, as depicted by spacing ‘y’ in FIG. 1C. That is, there may be a trade-off between the smallest achievable dimension of each of the features from patterned photoresist layer 110 and the spacing between each feature.

Thus, a method of self-aligned pillar patterning using multiple spacer masks is described herein.

### BRIEF DESCRIPTION OF THE DRAWINGS

FIGS. 1A-C illustrate cross-sectional views representing a conventional semiconductor lithographic process, in accordance with the prior art.

FIGS. 2A-B illustrate cross-sectional views representing pillar masks formed by using multiple spacer masks, in accordance with an embodiment of the present invention.

FIG. 3 is a flowchart representing a series of steps in a self-aligned pillar patterning process using two spacer masks, in accordance with an embodiment of the present invention.

FIGS. 4A-O′ illustrate cross-sectional and top-down views representing the series of steps from the flowchart of FIG. 3 as applied to a semiconductor stack, in accordance with an embodiment of the present invention.

FIGS. 5A-C illustrate top-down and angle views representing a series of steps in a non-orthogonal self-aligned pillar patterning process using two spacer masks, in accordance with an embodiment of the present invention.

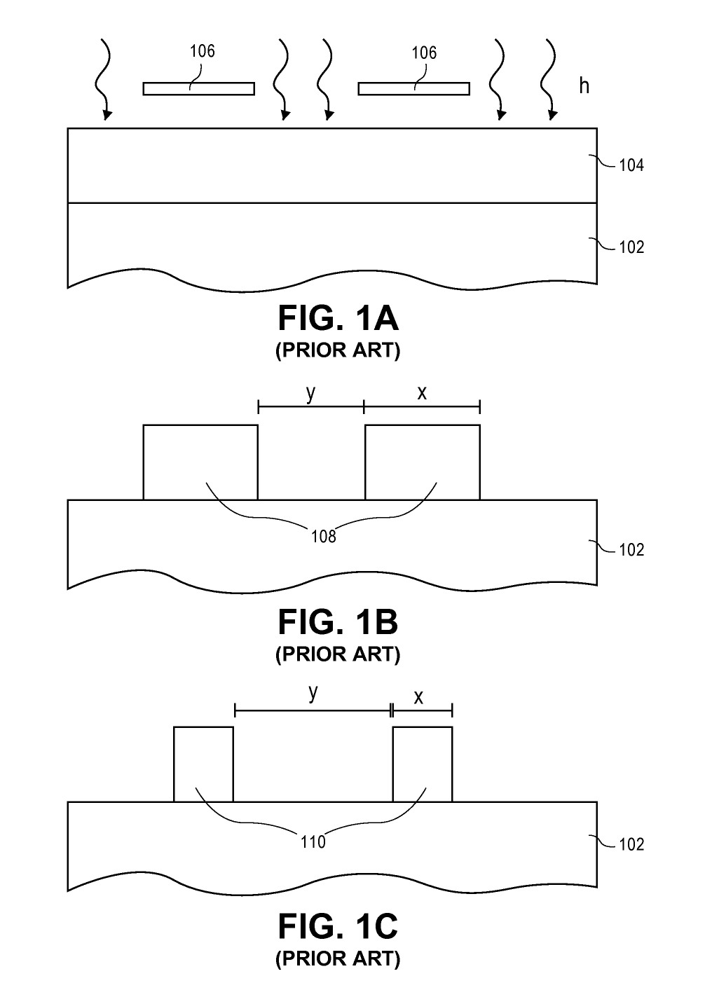

### DETAILED DESCRIPTION

A method of self-aligned pillar patterning using multiple spacer masks is described. In the following description, numerous specific details are set forth, such as fabrication conditions and material regimes, in order to provide a thorough understanding of the present invention. It will be apparent to one skilled in the art that the present invention may be practiced without these specific details. In other instances, well-known features, such as integrated circuit design layouts or photoresist development processes, are not described in detail in order to not unnecessarily obscure the present invention. Furthermore, it is to be understood that the various embodiments shown in the FIGS. are illustrative representations and are not necessarily drawn to scale.

Disclosed herein is a method for fabricating a semiconductor mask. The image of a series of lines from a first spacer mask may first be provided to a mask layer to form a patterned mask layer. In an embodiment, the image of a series of lines from a second spacer mask is then provided to the patterned mask layer to form a pillar mask comprised of a series of pillars. The image of the series of lines from the second spacer mask is non-parallel with the series of lines from the first spacer mask. In one embodiment, the image of the series of lines from the second spacer mask is orthogonal with the series of lines from the first spacer mask. Thus, each pillar of the pillar mask has a square shape. In an alternative embodiment, the image of the series of lines from the second spacer mask is at an angle θ relative to the series of lines from the first spacer mask, where 45°<θ<90°. Thus, each pillar of the pillar mask has a diamond shape.

The frequency of a lithographic pattern may be doubled by fabricating a spacer mask. For example, in accordance with an embodiment of the present invention, a spacer mask is fabricated having spacer lines formed adjacent to the sidewalls of a lithographically patterned sacrificial mask. That is, for every line in the sacrificial mask, two spacer lines of the spacer mask are generated. A semiconductor patterning mask providing substantially the same critical dimension for each line, i.e. the same feature width, but having double the density of lines in a particular region may thus be fabricated upon removal of the sacrificial mask. For example, in accordance with an embodiment of the present invention, the pitch of the sacrificial mask is selected to be 4 in order to ultimately provide a spacer mask having a pitch of 2.

A pillar etch mask may be fabricated by iteratively transferring the images of two distinct spacer masks into a hardmask layer. That is, in accordance with an embodiment of the present invention, the image of a first spacer mask is first transferred to an underlying hardmask layer and the first spacer mask is then removed to leave a patterned hardmask layer. A second spacer mask is then formed above the patterned hardmask layer. The lines of the second mask layer are formed non-parallel to the image of the lines of the first spacer mask that were initially transferred to the hardmask layer. Thus, upon transfer of the image of the second spacer mask to the patterned hardmask layer, a pillar hard mask is formed. The image of the pillar hardmask may then be transferred to a mask stack to form a pillar etch mask. The pillar etch mask is comprised of a series of self-aligned pillars, each having the same shape and dimension. The pillars are self-aligned because the size and shape of each pillar will be the same regardless of any offset between the first and second spacer masks, so long as the angle between the spacer masks is kept the same. In one embodiment, the lines of the second spacer mask are formed orthogonal to the image of the lines of the first spacer mask and the resulting pillar etch mask is comprised of a series of square pillars. In another embodiment, the lines of the second spacer mask are formed non-orthogonal to the image of the lines of the first spacer mask and the resulting pillar etch mask is comprised of a series of diamond-shaped pillars. The density of the pillars in a pillar etch mask formed from two spacer masks is quadruple the density that would otherwise be achieved by using the two sacrificial masks used to form the two spacer masks because each spacer mask on its own doubles the frequency of the features.

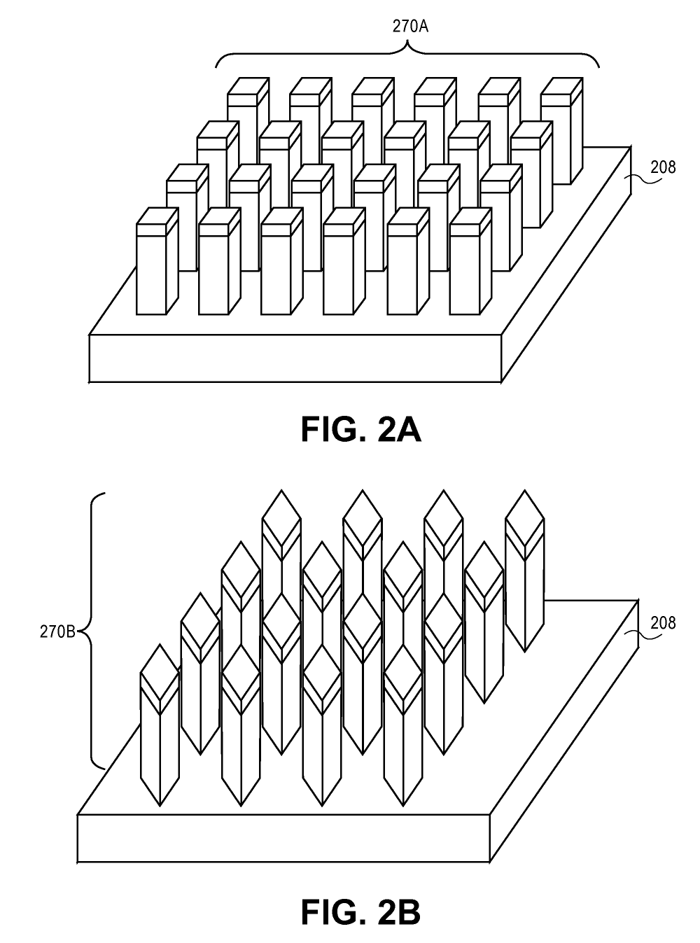

A pillar etch mask may be formed by using multiple spacer masks. FIGS. 2A-B illustrate cross-sectional views representing pillar etch masks formed by using two spacer masks, in accordance with an embodiment of the present invention.

Referring to FIG. 2A, a pillar etch mask 270A comprises a series of square pillars above a substrate or semiconductor layer 208. In accordance with an embodiment of the present invention, pillar etch mask 270A is formed by the iterative use of two spacer masks, each orthogonal to the other. In one embodiment, pillar mask 270A having square pillars is used to pattern a semiconductor layer 208 to fabricate a series of semiconductor structures for use in a flash device. Referring to FIG. 2B, a pillar etch mask 270B comprises a series of diamond-shaped pillars above a substrate or semiconductor layer 208. In accordance with an embodiment of the present invention, pillar etch mask 270B is formed by the iterative use of two spacer masks, each non-orthogonal yet non-parallel to the other. In one embodiment, pillar mask 270B having diamond-shaped pillars is used to pattern a semiconductor layer 208 to fabricate a series of semiconductor structures for use in a DRAM device.

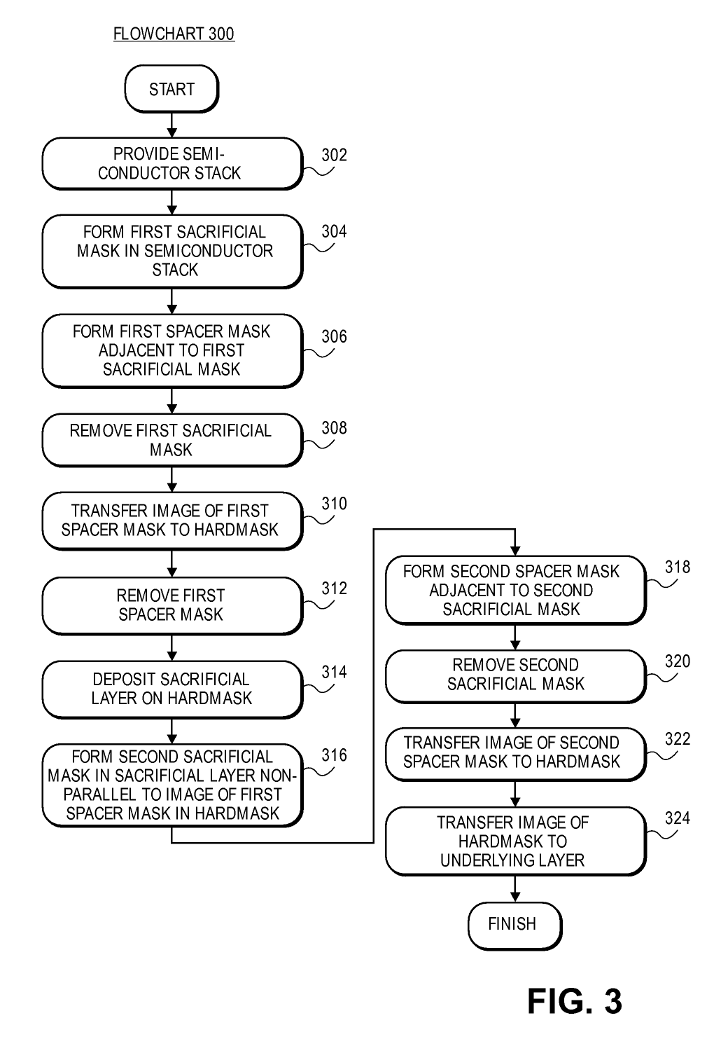

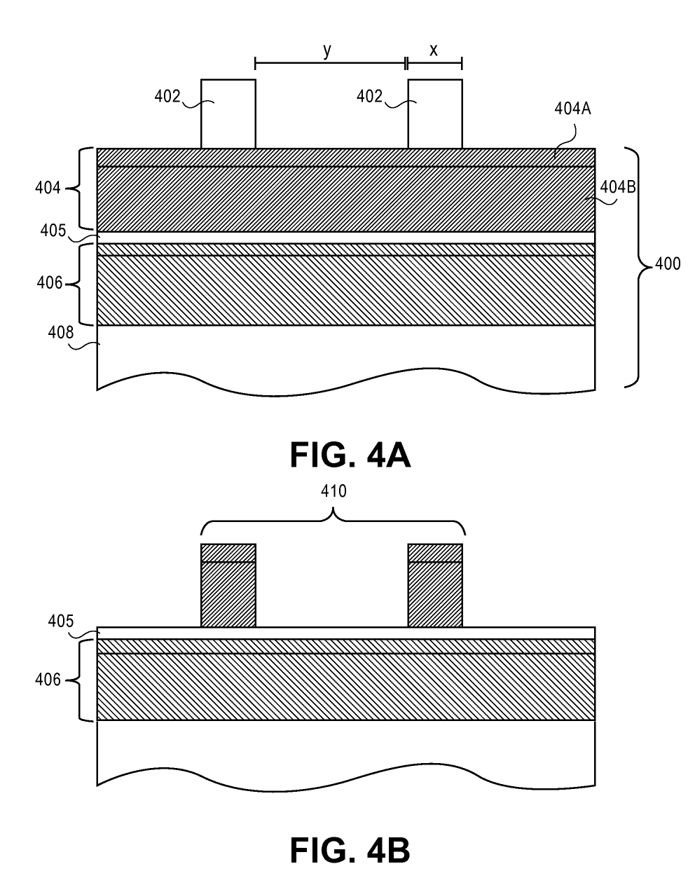

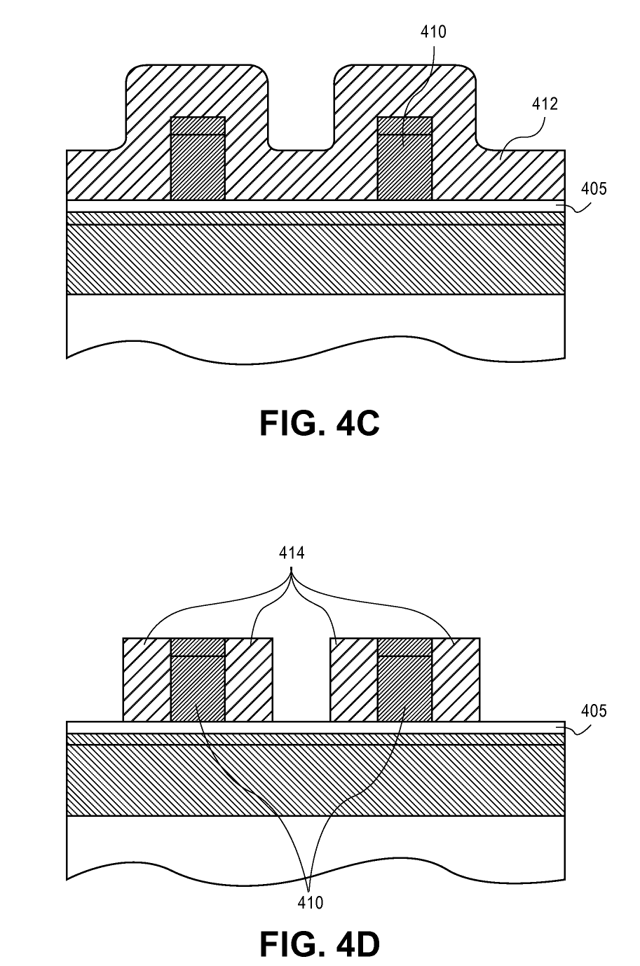

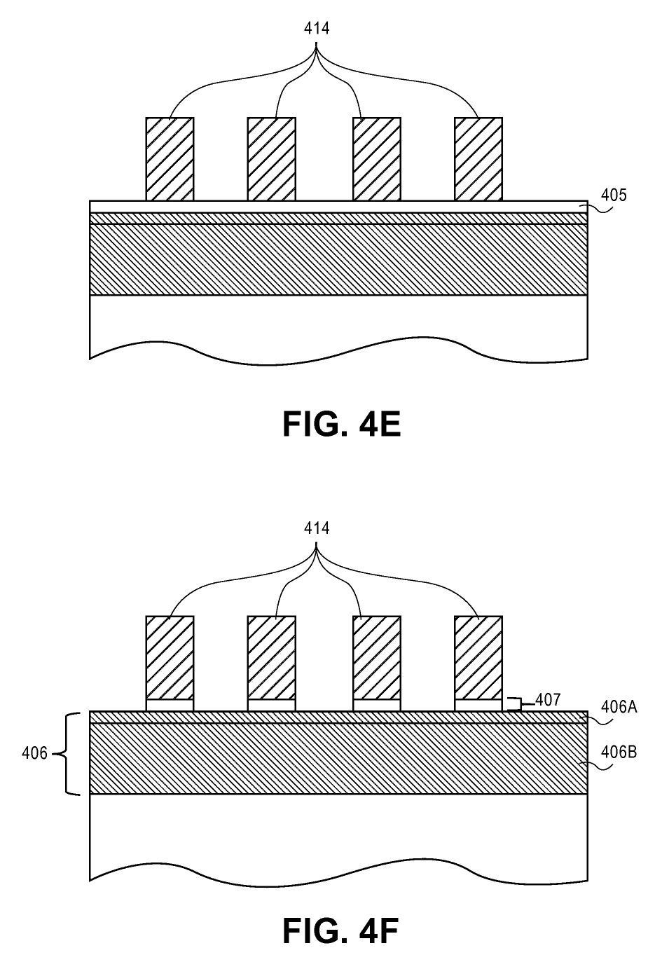

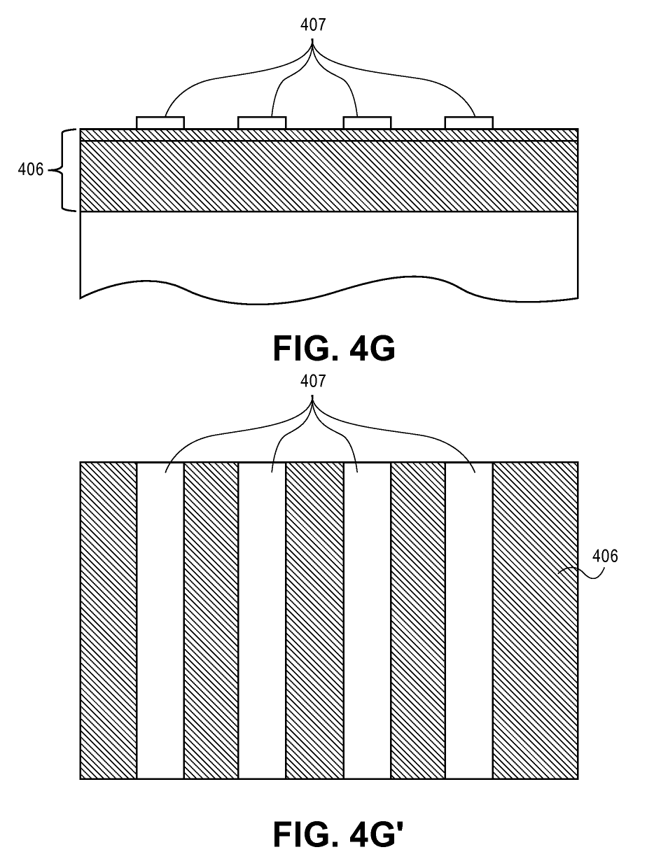

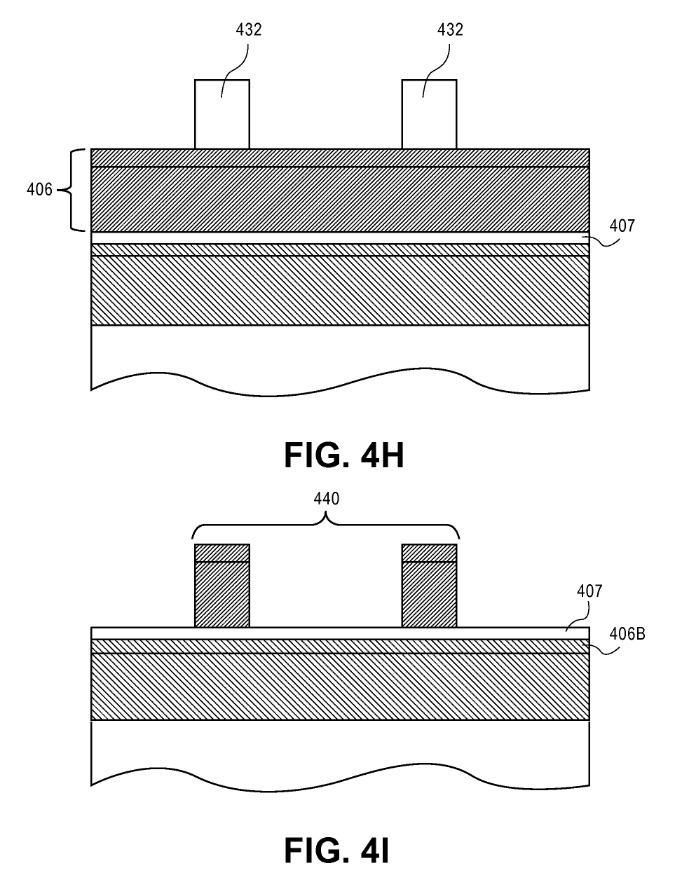

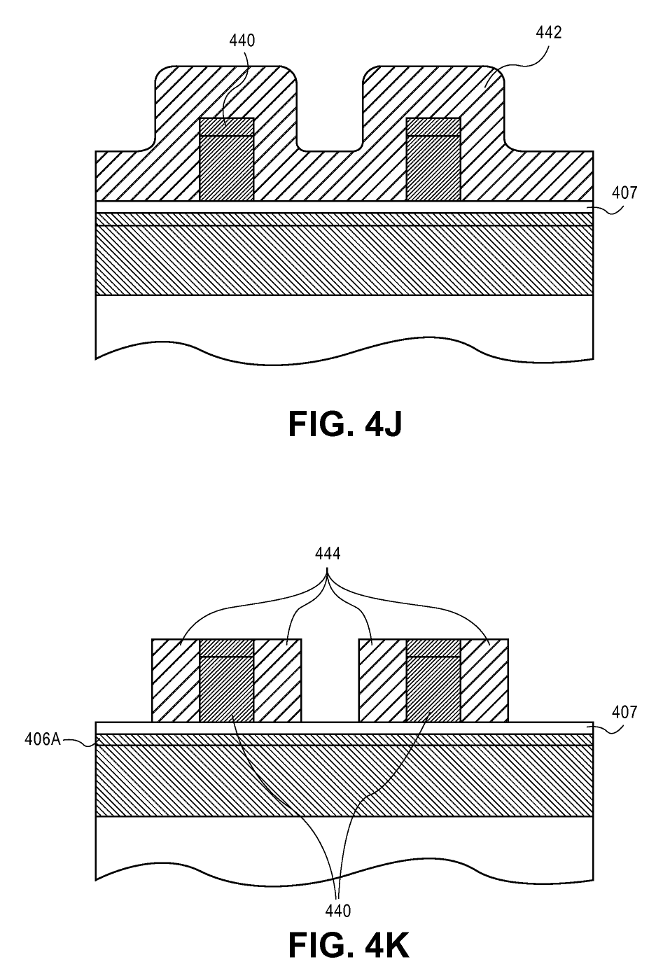

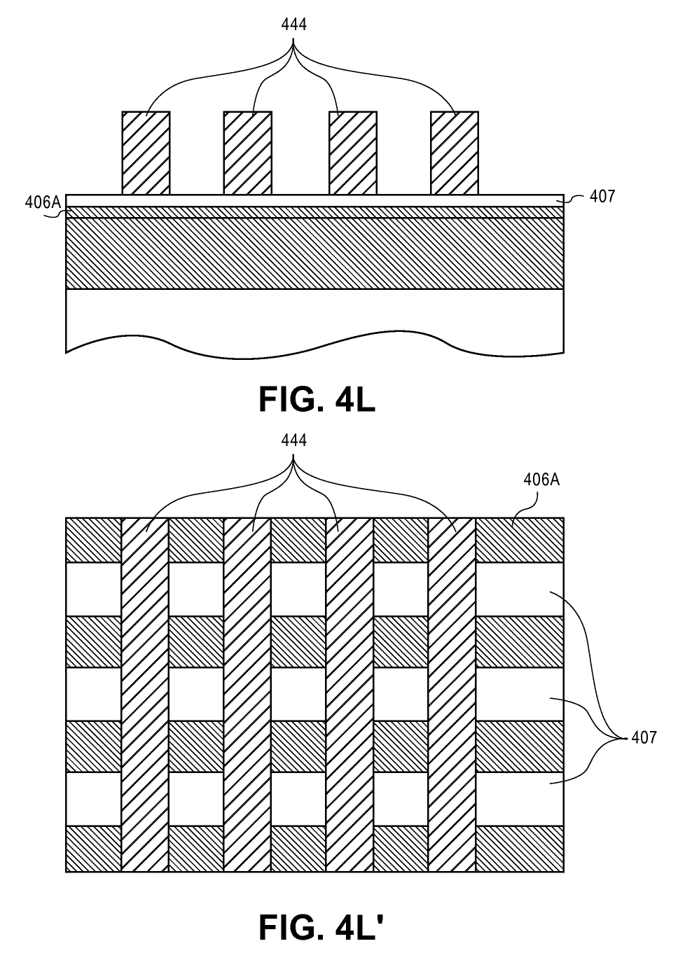

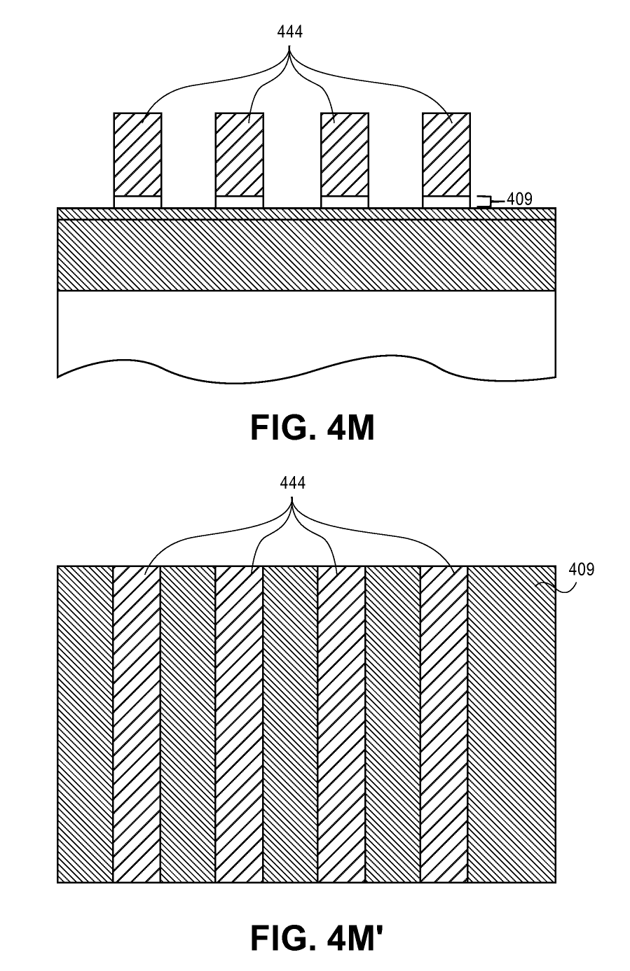

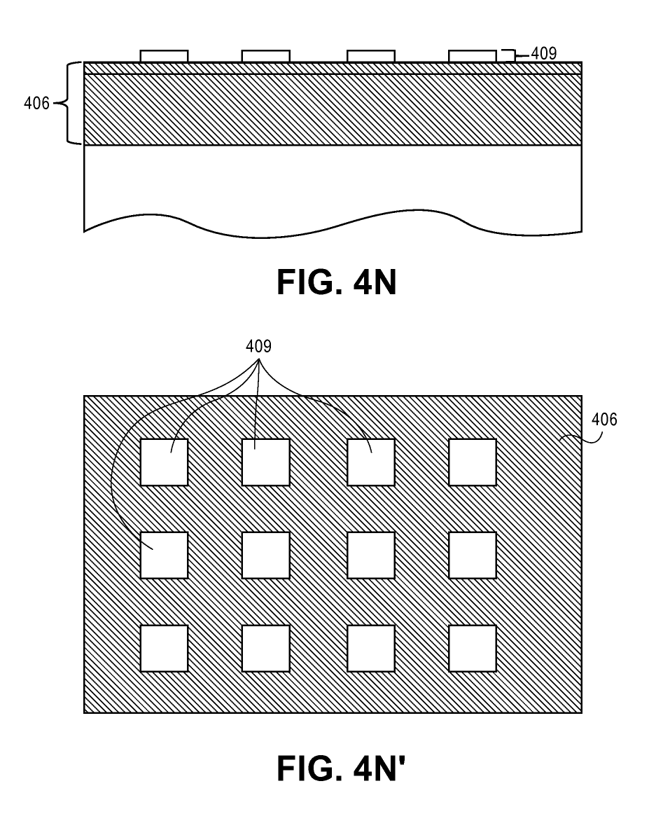

The fabrication of a pillar etch mask may include the iterative use of two spacer masks. FIG. 3 is a flowchart representing a series of steps in a self-aligned pillar patterning process using two spacer masks, in accordance with an embodiment of the present invention. FIGS. 4A-O′ illustrate cross-sectional and top-down views representing the series of steps from the flowchart of FIG. 3 as applied to a semiconductor stack, in accordance with an embodiment of the present invention.

Referring to step 302 of flowchart 300 and corresponding FIG. 4A, a semiconductor stack 400 comprised of a first mask stack 404, an intermediate hardmask layer 405 and a second mask stack 406 above a semiconductor layer 408 is provided. A patterned photoresist layer 402 is provided above semiconductor stack 400. Patterned photoresist layer will be used to form a first sacrificial mask in first mask stack 404 of semiconductor stack 400.

Patterned photoresist layer 402 may be comprised of any material suitable for use in a lithographic process. That is, patterned photoresist layer 402 may be formed by first masking a blanket layer of photoresist material and then exposing it to a light source. Patterned photoresist layer 402 may then be formed by developing the blanket photoresist layer. In an embodiment, the portions of the photoresist layer exposed to the light source are removed upon developing the photoresist layer, i.e. patterned photoresist layer 402 is comprised of a positive photoresist material. In a specific embodiment, patterned photoresist layer 402 is comprised of a positive photoresist material selected from the group consisting of a 248 nm resist, a 193 nm resist, a 157 nm resist and a phenolic resin matrix with a diazonaphthoquinone sensitizer. In another embodiment, the portions of the photoresist layer exposed to the light source are retained upon developing the photoresist layer, i.e. patterned photoresist layer 402 is comprised of a negative photoresist material. In a specific embodiment, patterned photoresist layer 402 is comprised of a negative photoresist material selected from the group consisting of poly-cis-isoprene and poly-vinyl-cinnamate.

Patterned photoresist layer 402 may have any dimensions suitable for a spacer mask fabrication process. In accordance with an embodiment of the present invention, the width ‘x’ of each feature of patterned photoresist layer 402 is selected to substantially correlate with the desired critical dimension of a semiconductor device feature, e.g. the width of a pillar that defines a gate electrode. In one embodiment, the width ‘x’ is in the range of 10-100 nanometers. The spacing between lines ‘y’ may be selected to optimize a first frequency doubling scheme. That is, in accordance with an embodiment of the present invention, a subsequently fabricated spacer mask is targeted such that the width of the spacer lines of the spacer mask are substantially the same as the width ‘x’ of each feature of patterned photoresist layer 402. Furthermore, the spacing between subsequently formed spacer lines is targeted to be substantially equal to the width of each spacer region. Thus, in one embodiment, because the frequency of the first spacer mask will ultimately be doubled, the spacing ‘y’ between each feature in patterned photoresist 402 is approximately equal to 3 times the value ‘x,’ as depicted in FIG. 4A. That is, the pitch of patterned photoresist layer 402 is selected to be approximately 4 in order to ultimately provide a first spacer mask with spacer lines having a pitch of approximately 2.

The approximate 3:1 spacing:width ratio for the features of patterned photoresist layer 402 may be achieved by over-exposing a positive photoresist layer at the exposure step or by trimming a photoresist layer subsequent to a lithographic/development process. In one embodiment, patterned photoresist 402 is comprised of 193 nm positive photoresist that was trimmed post development by using a plasma etch chemistry. Although for a frequency doubling scheme the ideal width of each feature in patterned photoresist layer 402 is ¼ the pitch of patterned photoresist layer 402, the initial targeted width may be required to be slightly thicker to compensate for the etch process used to pattern first mask stack 404. Thus in accordance with an embodiment of the present invention, the initial width of each line in patterned photoresist layer 402 is targeted to be between 0.281 and 0.312 times the pitch.

Referring to step 304 of flowchart 300 and corresponding FIG. 4B, the image of patterned photoresist layer 402 is transferred to first mask stack 404 by an etch process to form a first sacrificial mask 410. The etch process used to transfer the image may be any process suitable to transfer substantially the same image from patterned photoresist layer 402 to first mask stack 404.

First mask stack 404 and, hence, first sacrificial mask 410 may be comprised of any material or combination of materials suitable to act as a sacrificial mask in a spacer mask fabrication process. In accordance with an embodiment of the present invention, first mask stack 404 is comprised of a single material, as indicated by the single shading depicted in FIG. 4A. The composition and thickness of first mask stack 404 comprised of a single material may be suitable for etching with an etch process that is substantially non-impactful to patterned photoresist layer 402. That is, in one embodiment, the dimensions and etch characteristics of first mask stack 404 comprised of a single material are selected to be amenable to patterning during which patterned photoresist layer 402 is retained substantially intact. In a specific embodiment, patterned photoresist layer 402 is comprised of a carbon-based material and first mask stack 404 is comprised of a material selected from the group consisting of silicon nitride, silicon oxide and amorphous or polycrystalline silicon. In a particular embodiment, first mask stack 404 is comprised substantially of silicon nitride and the etch process used to form first sacrificial mask 410 utilizes gases selected from the group consisting of CH₂F₂ and CHF₃. In another particular embodiment, first mask stack 404 is comprised substantially of silicon oxide and the etch process used to form first sacrificial mask 410 utilizes gases selected from the group consisting of C₄F₈ and CHF₃. In another particular embodiment, first mask stack 404 is comprised substantially of amorphous or polycrystalline silicon and the etch process used to form first sacrificial mask 410 utilizes gases selected from the group consisting of Cl₂ and HBr. In accordance with an embodiment of the present invention, the thickness of first mask stack 404 comprised of a single material is selected to optimize the subsequent formation of a spacer mask in a frequency doubling scheme. The thickness of first mask stack 404 may be sufficiently small to prevent spacer mask line-collapse of a subsequently formed spacer mask and sufficiently large to enable critical dimension control of the spacer mask lines. In one embodiment, the thickness of first mask stack 404 comprised of a single material is in the range of 4.06-5.625 times the targeted line width of first sacrificial mask 410.

In accordance with an alternative embodiment of the present invention, first mask stack 404 is comprised of a first hardmask layer 404A above a first mask layer 404B, as indicated by the two layers depicted in FIG. 4A. Hence, first sacrificial mask 410 is comprised of a sacrificial hardmask portion 410A above a sacrificial mask portion 410B, as depicted in FIG. 4B. In one embodiment, first hardmask layer 404A and first mask layer 404B are patterned with the image of patterned photoresist layer 402 in two distinct etch steps. First hardmask layer 404A may be comprised of any material suitable for etching with an etch process that is substantially non-impactful to patterned photoresist layer 402. That is, in one embodiment, the dimensions and etch characteristics of first hardmask layer 404A are selected to be amenable to a patterning process during which patterned photoresist layer 402 is retained substantially intact. In a specific embodiment, first mask layer 404B (which underlies first hardmask layer 404A) is comprised of a material with etch characteristics similar to the etch characteristics of patterned photoresist layer 402. Thus, first hardmask layer 404A is used to preserve the image from patterned photoresist layer 402 during the subsequent etch of first mask layer 404B. In a specific embodiment, patterned photoresist layer 402 and first mask layer 404B are comprised of carbon-based materials and first hardmask layer 404A is comprised of a material selected from the group consisting of silicon nitride, silicon oxide and amorphous or polycrystalline silicon. In a particular embodiment, first hardmask layer 404A is comprised substantially of silicon nitride and the etch process used to pattern first hardmask layer 404A selective to patterned photoresist layer 402 and first mask layer 404B utilizes gases selected from the group consisting of CH₂F₂ and CHF₃. In another particular embodiment, first hardmask layer 404A is comprised substantially of silicon oxide and the etch process used to pattern first hardmask layer 404A selective to patterned photoresist layer 402 and first mask layer 404B utilizes gases selected from the group consisting of C₄F₈ and CHF₃. In another particular embodiment, first hardmask layer 404A is comprised substantially of amorphous or polycrystalline silicon and the etch process used to pattern first hardmask layer 404A selective to patterned photoresist layer 402 and first mask layer 404B utilizes gases selected from the group consisting of Cl₂ and HBr. The thickness of first hardmask layer 404A may be sufficiently small to enable highly selective etching relative to patterned photoresist layer 402 and sufficiently large to avoid pinholes that may undesirably expose first mask layer 404B. In one embodiment, the thickness of first hardmask layer 404A is in the range of 20-50 nanometers.

In the case where first mask stack 404 is comprised of a first hardmask layer 404A above a first mask layer 404B, first mask layer 404B may be comprised of any material suitable to withstand a controlled etch process and a subsequent spacer mask formation process. In one embodiment, first mask layer 404B has similar etch characteristics to patterned photoresist layer 402. In a specific embodiment, the thicknesses of patterned photoresist layer 402 and first mask layer 404B are selected such that all portions of patterned photoresist layer 402 remaining subsequent to the etch of first hardmask layer 404A are removed during the etch of first mask layer 404B. For example, in accordance with an embodiment of the present invention, both patterned photoresist layer 402 and first mask layer 404B are comprised substantially of carbon atoms. In one embodiment, first mask layer 404B is comprised of a mixture of sp³ (diamond-like)-, sp²(graphitic)- and sp¹(pyrolitic)-hybridized carbon atoms formed from a chemical vapor deposition process using hydrocarbon precursor molecules. Such a film may be known in the art as an amorphous carbon film. In a specific embodiment, first mask layer 404B is comprised of such an amorphous carbon film and is etched by using gases selected from the group consisting of the combination of O₂ and N₂ or the combination of CH₄ and N₂ and O₂. In a particular embodiment, substantially all of patterned photoresist layer 402 is removed in the same etch step as that used to pattern first mask layer 404B. The thickness of first mask layer 404B may be sufficiently small to prevent spacer mask line-collapse of a subsequently formed spacer mask and sufficiently large to enable critical dimension control of the spacer mask lines. In one embodiment, the total thickness of first mask stack 404 comprised of first hardmask layer 404A and first mask layer 404B is in the range of 4.06-5.625 times the targeted line width of first sacrificial mask 410.

Referring again to FIG. 4B, first mask stack 404 is patterned to form first sacrificial mask 410 selective to intermediate hardmask layer 405, which protects second mask stack 406 until required for future processing. Intermediate hardmask layer 405 may have any properties suitable to protect second mask stack 406 from the etch process used to form first sacrificial mask 410. In accordance with an embodiment of the present invention, first mask stack 404 is comprised of a single material and is etched selective to intermediate hardmask layer 405. In one embodiment, first mask stack 404 is comprised of silicon nitride and intermediate hardmask layer 405 is comprised of a material selected from the group consisting of silicon oxide and amorphous or polycrystalline silicon. In another embodiment, first mask stack 404 is comprised of silicon oxide and intermediate hardmask layer 405 is comprised of a material selected from the group consisting of silicon nitride and amorphous or polycrystalline silicon. In another embodiment, first mask stack 404 is comprised of amorphous or polycrystalline silicon and intermediate hardmask layer 405 is comprised of a material selected from the group consisting of silicon nitride and silicon oxide. In accordance with an alternative embodiment of the present invention, first mask stack 404 is comprised of a first hardmask layer 404A and a first mask layer 404B. In one embodiment, first mask layer 404B is comprised of an amorphous carbon film etched by gases selected from the group consisting of the combination of O₂ and N₂ or the combination of CH₄ and N₂ and O₂ and intermediate hardmask layer 405 is comprised of a material selected from the group consisting of silicon nitride, silicon oxide and amorphous or polycrystalline silicon. The thickness of intermediate hardmask layer 405 may be sufficiently small to enable subsequent highly selective etching relative to second mask stack 406 and sufficiently large to avoid pinholes that may undesirably expose second mask stack 406 to the etch process applied to first mask stack 404. In one embodiment, the thickness of intermediate hardmask layer 405 is in the range of 15-40 nanometers.

Referring to step 306 of flowchart 300 and corresponding FIG. 4C, a spacer layer 412 is deposited conformal with first sacrificial mask 410 and above intermediate hardmask layer 405. Spacer layer 412 is the source of material for what will ultimately become the first spacer mask for use in a self-aligned pillar patterning scheme.

Spacer layer 412 may be comprised of any material suitable to form a reliable mask for use in a subsequent etch process. In accordance with an embodiment of the present invention, spacer layer 412 is comprised of a material selected from the group consisting of silicon nitride, silicon oxide and amorphous or polycrystalline silicon. Spacer layer 412 may be deposited by any process suitable to provide a conformal layer on the sidewalls of first sacrificial mask 410, as depicted in FIG. 4C. In one embodiment, spacer layer 412 is deposited by a chemical vapor deposition (CVD) technique selected from the group consisting of molecular-organic CVD, low-pressure CVD and plasma-enhanced CVD. The thickness of spacer layer 410 may be selected to determine the width of the features in a subsequently formed spacer mask. Thus, in accordance with an embodiment of the present invention, the thickness of spacer layer 410 is substantially the same as the width of the features of first sacrificial mask 410, as depicted in FIG. 4C. Although for a frequency doubling scheme the ideal thickness of spacer layer 412 is the same as the width of the features of first sacrificial mask 410, the initial targeted width may be required to be slightly thicker to compensate for the etch process used to pattern spacer layer 412. In one embodiment, the thickness of spacer layer 412 is approximately 1.06 times the width of the features of first sacrificial mask 410, i.e. 1.06 times the desired feature width of the lines in a subsequently formed spacer mask.

Referring again to step 306 of flowchart 300 and now to corresponding FIG. 4D, spacer layer 412 is etched to provide first spacer mask 414 and to expose the top surfaces of first sacrificial mask 410 and intermediate hardmask layer 405. The lines of first spacer mask 414 are conformal with the sidewalls of the features of first sacrificial mask 410. Thus, there are two lines from first spacer mask 414 for every line of first sacrificial mask 410, as depicted in FIG. 4D.

Spacer layer 412 may be etched by any process suitable to provide well-controlled dimensions, i.e. to maintain a width of critical dimension of first sacrificial mask 410. In accordance with an embodiment of the present invention, spacer layer 412 is etched until the lines of first spacer mask 414 are substantially the same height as the features of first sacrificial mask 410, as depicted in FIG. 4D. However, in another embodiment, the lines of first spacer mask 414 are recessed slightly below the top surface of the features of first sacrificial mask 410 in order to ensure that the continuity of spacer layer 412 is broken above and between the lines of first spacer mask 414. Spacer layer 412 may be etched such that the spacer lines of first spacer mask 414 retain a substantial portion of the original thickness of spacer layer 412. In a particular embodiment, the width of the top surface of each line of first spacer mask 414 is substantially the same as the width at the interface of first spacer mask 414 and intermediate hardmask layer 405, as depicted in FIG. 4D.

Spacer layer 412 may also be etched to form first spacer mask 414 with high etch selectivity to first sacrificial mask 410 and intermediate hardmask layer 405. In a particular embodiment, first sacrificial mask 410 is a single layer mask and the desired etch selectivity is with respect to the single layer. In another particular embodiment, first sacrificial mask 410 is a stacked layer and the desired etch selectivity is with respect to a sacrificial hardmask portion, i.e. with respect to the material of first hardmask layer 404A. Thus, in accordance with an embodiment of the present invention, spacer layer 412 and, hence, first spacer mask 414 is comprised of a material different than the materials of the top portion of first sacrificial mask 410 and intermediate hardmask layer 405. In one embodiment, the top portion of first sacrificial mask 410 is comprised of silicon nitride, intermediate hardmask layer 405 is comprised of silicon oxide and spacer layer 412 is comprised of amorphous or polycrystalline silicon and is etched to form first spacer mask 414 with a dry etch process using a plasma generated from the gases Cl₂ or HBr. In another embodiment, the top portion of first sacrificial mask 410 is comprised of silicon oxide, intermediate hardmask layer 405 is comprised of silicon nitride and spacer layer 412 is comprised of amorphous or polycrystalline silicon and is etched to form first spacer mask 414 with a dry etch process using a plasma generated from the combination of the gases Cl₂ and HBr. In another embodiment, the top portion of first sacrificial mask 410 is comprised of amorphous or polycrystalline silicon, intermediate hardmask layer 405 is comprised of silicon nitride and spacer layer 412 is comprised of silicon oxide and is etched to form first spacer mask 414 with a dry etch process using a plasma generated from the gas C₄F₈. In another embodiment, the top portion of first sacrificial mask 410 is comprised of amorphous or polycrystalline silicon, intermediate hardmask layer 405 is comprised of silicon oxide and spacer layer 412 is comprised of silicon nitride and is etched to form first spacer mask 414 with a dry etch process using a plasma generated from the gas CH₂F₂. In another embodiment, the top portion of first sacrificial mask 410 is comprised of silicon oxide, intermediate hardmask layer 405 is comprised of amorphous or polycrystalline silicon and spacer layer 412 is comprised of silicon nitride and is etched to form first spacer mask 414 with a dry etch process using a plasma generated from the combination of the gases CHF₃ and CH₂F₂. In another embodiment, the top portion of first sacrificial mask 410 is comprised of silicon nitride, intermediate hardmask layer 405 is comprised of amorphous or polycrystalline silicon and spacer layer 412 is comprised of silicon oxide and is etched to form first spacer mask 414 with a dry etch process using a plasma generated from the gas CHF₃. In a specific embodiment of the present invention, the etch process used to for first spacer mask 414 is end-pointed upon exposure of the top surfaces of first sacrificial mask 410 and intermediate hardmask layer 405. In a particular embodiment, a slight over-etch is applied following the end-point detection to ensure that the lines of first spacer mask 414 are discontinuous from feature to feature (e.g. line-to-line) of first sacrificial mask 410.

Referring to step 308 of flowchart 300 and corresponding FIG. 4E, first sacrificial mask 410 is removed. Thus, in accordance with an embodiment of the present invention, first sacrificial mask 410 is used to define the spacing and location of first spacer mask 414 and then removed to leave only first spacer mask 414 having double the frequency of first sacrificial mask 410.

First sacrificial mask 410 may be removed by any technique that is highly selective to first spacer mask 414 and intermediate hardmask layer 405. In accordance with an embodiment of the present invention, first sacrificial mask 410 is comprised of a single layer and is removed selective to first spacer mask 414 in a single process step. In one embodiment, first spacer mask 414 is comprised of amorphous or polycrystalline silicon, intermediate hardmask layer 405 is comprised of silicon oxide and first sacrificial mask 410 is comprised substantially of silicon nitride and is removed by a single etch step selected from the group consisting of a hot H₃PO₄ wet etch or a SiCoNi etch. In another embodiment, first spacer mask 414 is comprised of amorphous or polycrystalline silicon, intermediate hardmask layer 405 is comprised of silicon nitride and first sacrificial mask 410 is comprised substantially of silicon oxide and is removed by a single etch step selected from the group consisting of an aqueous hydrofluoric acid wet etch or a SiCoNi etch. In another embodiment, first spacer mask 414 is comprised of silicon oxide, intermediate hardmask layer 405 is comprised of silicon nitride and first sacrificial mask 410 is comprised substantially of amorphous or polycrystalline silicon and is removed by a single etch step selected from the group consisting of a Cl₂ plasma etch and a CF₄/O₂ plasma etch. In another embodiment, first spacer mask 414 is comprised of silicon nitride, intermediate hardmask layer 405 is comprised of silicon oxide and first sacrificial mask 410 is comprised substantially of amorphous or polycrystalline silicon and is removed by a single etch step selected from the group consisting of a Cl₂ plasma etch and a CF₄/O₂ plasma etch. In another embodiment, first spacer mask 414 is comprised of silicon nitride, intermediate hardmask layer 405 is comprised of amorphous or polycrystalline silicon and first sacrificial mask 410 is comprised substantially of silicon oxide and is removed by a single etch step selected from the group consisting of an aqueous hydrofluoric acid wet etch or a SiCoNi etch. In another embodiment, first spacer mask 414 is comprised of silicon oxide, intermediate hardmask layer 405 is comprised of amorphous or polycrystalline silicon and first sacrificial mask 410 is comprised substantially of silicon nitride and is removed by a single etch step selected from the group consisting of a hot H₃PO₄ wet etch or a SiCoNi etch.

In an alternative embodiment, first sacrificial mask 410 is comprised of a sacrificial hardmask portion above a sacrificial mask portion, as described in an alternative embodiment associated with FIG. 4B. For example, in one embodiment, the sacrificial hardmask portion is comprised of a material selected from the group consisting of silicon nitride, silicon oxide and amorphous or polycrystalline silicon, while the sacrificial mask portion is comprised of an amorphous carbon material, such as the amorphous carbon material described in association with first mask layer 404B. Thus, in accordance with an embodiment of the present invention, the same material combinations and etch processes embodied above for removing first sacrificial mask 410 selective to first spacer mask 414 and intermediate hardmask layer 405 are used to remove a sacrificial hardmask portion selective to first spacer mask 414 and intermediate hardmask layer 405. The sacrificial mask portion underlying the sacrificial hardmask portion of a stacked sacrificial mask may be substantially removed in the same etch step that is used to remove the sacrificial hardmask portion. Alternatively, a second etch step may be required the sacrificial mask portion. In one embodiment, the sacrificial mask portion is comprised of amorphous carbon and is removed with a dry etch having a plasma comprised of gases selected from the group consisting of the combination of O₂ and N₂ or the combination of CH₄, N₂ and O₂.

Referring to step 310 of flowchart 300 and corresponding FIG. 4F, the image of first spacer mask 414 is transferred to intermediate hardmask layer 405 to form patterned intermediate hardmask layer 407. Patterned intermediate hardmask layer 407 is formed selective to second mask stack 406, as depicted in FIG. 4F.

Second mask stack 406 is comprised of a second hardmask layer 406A above a second mask layer 406B, as depicted in FIG. 4F. Second hardmask layer 406A may have any properties suitable to protect second mask layer 406B from the etch process used to form patterned intermediate hardmask layer 407. In accordance with an embodiment of the present invention, intermediate hardmask layer 405 is comprised of a single material and is etched selective to first spacer mask 414 and second hardmask layer 406A. In one embodiment, intermediate hardmask layer 405 is comprised of silicon nitride, first spacer mask 414 is comprised of silicon oxide and second hardmask layer 406A is comprised of amorphous or polycrystalline silicon. In another embodiment, intermediate hardmask layer 405 is comprised of silicon nitride, first spacer mask 414 is comprised of amorphous or polycrystalline silicon and second hardmask layer 406A is comprised of silicon oxide. In another embodiment, intermediate hardmask layer 405 is comprised of silicon oxide, first spacer mask 414 is comprised of silicon nitride and second hardmask layer 406A is comprised of amorphous or polycrystalline silicon. In another embodiment, intermediate hardmask layer 405 is comprised of silicon oxide, first spacer mask 414 is comprised of amorphous or polycrystalline silicon and second hardmask layer 406A is comprised of silicon nitride. In another embodiment, intermediate hardmask layer 405 is comprised of amorphous or polycrystalline silicon, first spacer mask 414 is comprised of silicon nitride and second hardmask layer 406A is comprised of silicon oxide. In another embodiment, intermediate hardmask layer 405 is comprised of amorphous or polycrystalline silicon, first spacer mask 414 is comprised of silicon oxide and second hardmask layer 406A is comprised of silicon nitride. In a specific embodiment, intermediate hardmask layer 405 is comprised of a material and is etched with a corresponding etch process the same as the material/etch combinations used to pattern first hardmask layer 404A, described in association with FIG. 4B. The thickness of second hardmask layer 406A may be sufficiently small to enable subsequent highly selective etching relative to second mask layer 406B and sufficiently large to avoid pinholes that may undesirably expose second mask layer 406B to the etch process applied to intermediate hardmask layer 405. In one embodiment, the thickness of second hardmask layer 406A is in the range of 15-40 nanometers.

Referring to step 312 of flowchart 300 and corresponding FIGS. 4G (cross-section) and 4G′ (top-down view), first spacer mask 414 is removed to provide only patterned intermediate hardmask layer 407 above second mask stack 406. Patterned intermediate hardmask layer 407 comprises the image of first spacer mask 414 and thus comprises a series of lines having double the frequency of the lines of first sacrificial mask 410, as depicted in the top-down view FIG. 4G′. First spacer mask 414 may be removed to enable the formation of a second spacer mask non-parallel to the image of first spacer mask 414 transferred to intermediate hardmask layer 405. In accordance with an embodiment of the present invention, first spacer mask 414 has a thickness to great to accommodate the formation of an overlaying second spacer mask. Thus, the image of first spacer mask 414 is transferred to intermediate hardmask layer 405, which has a thickness substantially less than the thickness of first spacer mask 414. The second spacer mask is then formed on patterned intermediate hardmask layer 407 in the fabrication of a self-aligned pillar mask. First spacer mask 414 may be removed selective to patterned intermediate hardmask layer 407 by any suitable etch used to pattern spacer layer 412, described in association with FIG. 4D.

Referring to step 314 of flowchart 300 and corresponding FIG. 4H, a third mask stack 430 is deposited above patterned intermediate hardmask layer 407. A patterned photoresist layer 432 is formed above third mask stack 430. This is the first step in the formation of a second spacer mask for use in a self-aligned pillar patterning scheme. Thus, in accordance with an embodiment of the present invention, the lines of patterned photoresist layer 432 are formed non-parallel to the lines of patterned intermediate hardmask layer 407. In one embodiment, the lines of patterned photoresist layer 432 are formed orthogonal to the lines of patterned intermediate hardmask layer 407, as depicted in FIG. 4H. Patterned photoresist layer 432 and third mask stack 430 may be comprised of any material or material combination and have any dimension as the materials and dimensions of patterned photoresist layer 402 and first mask stack 404, described in association with FIG. 4A.

Referring to step 316 of flowchart 300 and corresponding FIG. 4I, third mask stack 430 is patterned to form a second sacrificial mask 440 selective to patterned intermediate hardmask layer 407 and the corresponding exposed portions of second hardmask layer 406B. Thus, in accordance with an embodiment of the present invention, the lines of second sacrificial mask 440 are formed non-parallel to the lines of patterned intermediate hardmask layer 407. In one embodiment, the lines of second sacrificial mask 440 are formed orthogonal to the lines of patterned intermediate hardmask layer 407, as depicted in FIG. 4I. Second sacrificial mask 440 may be formed by any etch process used to form first sacrificial mask 410, described in association with FIG. 4B.

Referring to step 318 of flowchart 300 and corresponding FIG. 4J, a spacer layer 442 is deposited conformal with second sacrificial mask 440 and above patterned intermediate hardmask layer 407. Spacer layer 442 is the source of material for what will ultimately become the second spacer mask for use in a self-aligned pillar patterning scheme. Spacer layer 442 may be comprised of any material described in association with spacer layer 412 from FIG. 4C.

Referring again to step 318 of flowchart 300 and now to corresponding FIG. 4K, spacer layer 442 is etched to provide second spacer mask 444 and to expose the top surfaces of second sacrificial mask 440, patterned intermediate hardmask layer 407 and the portions of second hardmask layer 406A not covered by patterned intermediate hardmask layer 407. The lines of second spacer mask 444 are conformal with the sidewalls of the features of second sacrificial mask 440. Thus, there are two lines from second spacer mask 444 for every line of second sacrificial mask 440, as depicted in FIG. 4K. Spacer layer 442 may be etched by using any etch process used to etch spacer layer 412, as described in association with FIG. 4D. However, in accordance with an embodiment of the present invention, the etch process must additionally be selective to the portions of second hardmask layer 406A that are not covered by patterned intermediate hardmask layer 407.

Referring to step 320 of flowchart 300 and corresponding FIG. 4L (cross-section) and L′ (top-down view), second sacrificial mask 440 is removed selective to patterned intermediate hardmask layer 407 and the portions of second hardmask layer 406A not covered by patterned intermediate hardmask layer 407. Thus, in accordance with an embodiment of the present invention, second sacrificial mask 440 is used to define the spacing and location of second spacer mask 444 and then removed to leave only second spacer mask 444 having double the frequency of second sacrificial mask 440. The lines of second spacer mask 444 are non-parallel to the lines of patterned intermediate hardmask layer 407. In one embodiment, the lines of second spacer mask 444 are orthogonal to the lines of patterned intermediate hardmask layer 407, as depicted in FIG. 4L′. Second sacrificial mask 440 may be removed by using any etch process used to remove first sacrificial mask 410, as described in association with FIG. 4E. However, in accordance with an embodiment of the present invention, the removal process must additionally be selective to the portions of second hardmask layer 406A that are not covered by patterned intermediate hardmask layer 407.

Referring to step 322 of flowchart 300 and corresponding FIGS. 4M (cross-section) and 4M′ (top-down view), the image of second spacer mask 444 is transferred to patterned intermediate hardmask layer 407 to form pillar hardmask 409. Pillar hardmask 409 is formed selective to second mask stack 406, as depicted in FIGS. 4M and 4M′. Patterned intermediate hardmask layer 407 may be etched to form pillar hardmask 409 with any etch process used to form patterned intermediate hardmask layer 407 from intermediate hardmask layer 405, as described in association with FIG. 4F.

Referring to FIGS. 4N (cross-section) and 4N′ (top-down view), second spacer mask 444 is removed to provide only pillar hardmask 409 above second mask stack 406. Second spacer mask 444 may be removed by any process used to remove first spacer mask 414, described in association with FIG. 4G. Pillar hardmask 409 comprises an image resulting from the non-parallel overlaying of first spacer mask 414 with second spacer mask 444 and thus comprises a series of pillars. In one embodiment, pillar hardmask 409 comprises an image resulting from the orthogonal overlaying of first spacer mask 414 with second spacer mask 444 and thus comprises a series of square pillars, as depicted in FIG. 4G′. The density of the pillars is quadruple the density that would otherwise be achieved using first sacrificial mask 410 in conjunction with second sacrificial mask 440.

Referring to step 324 of flowchart 300 and corresponding FIGS. 4O (cross-section) and 4O′ (angle view), the image of pillar hardmask 409 is transferred to second mask stack 406 to form etch mask 470 above semiconductor layer 408. In one embodiment, second mask stack 406 is comprised substantially of a single material and is etched to form etch mask 470 in a single etch step. In a specific embodiment, second mask stack 406 is comprised substantially of a single material selected from the group consisting of silicon nitride, silicon oxide and amorphous or polycrystalline silicon. In an alternative embodiment, second mask stack 406 is comprised of second hardmask layer 406A above second mask layer 406B, as depicted in and described in association with FIG. 4B. Thus, in one embodiment, etch mask 470 is comprised of a hardmask portion 470A and a mask portion 470B, as depicted in FIGS. 4O and 4O′.

Embodiments for the material composition and thickness of second hardmask layer 406A and, hence, hardmask portion 470A were described in association with FIG. 4B. In accordance with an embodiment of the present invention, the image of pillar hardmask 409 is transferred into second hardmask layer 406A in an etch step distinct from the patterning step ultimately used to form mask portion 470B. In one embodiment, second hardmask layer 406A is comprised substantially of amorphous or polycrystalline silicon and is etched to form hardmask portion 470A with a dry etch using the gas CHF₃. In another embodiment, second hardmask layer 406A is comprised substantially of silicon oxide and is etched to form hardmask portion 470A with a dry etch using gases selected from the group consisting of CH₂F₂ and the combination of Cl₂ and HBr. In another embodiment, second hardmask layer 406A is comprised substantially of silicon nitride and is etched to form hardmask portion 470A with a dry etch using gases selected from the group consisting of C₄F₈, Cl₂ and HBr.

In accordance with an embodiment of the present invention, the image of pillar hardmask 409 is then transferred from hardmask portion 470A to a mask portion 470B in a second etch step. Second mask layer 406B and, hence, mask portion 470B of etch mask 470 may be comprised of any material suitable for substantially withstanding an etch process used to subsequently pattern semiconductor layer 408. In one embodiment, second mask layer 406B is comprised of an amorphous carbon material, such as the amorphous carbon material described in association with an embodiment of the composition of first mask layer 404B. In a particular embodiment, the thickness of second mask layer 406B and, hence, mask portion 470B of etch mask 370 is in the range of 3.125-6.875 times the width of each of the pillars of etch mask 470. Second mask layer 406B may be etched to form mask portion 470B by any etch process that maintains a substantially vertical profile for each of the lines of etch mask 470, as depicted in FIGS. 4O and 4O′. In one embodiment, second mask layer 406B is comprised of amorphous carbon and is removed with a dry etch process using a plasma comprised of gases selected from the group consisting of the combination of O₂ and N₂ or the combination of CH₄, N₂ and O₂.

Thus, a method to fabricate an etch mask 470 by using two spacer masks has been described. Etch mask 470 may then be used to pattern a semiconductor layer 408 for, e.g. device fabrication for an integrated circuit. In accordance with an embodiment of the present invention, etch mask 470 has a mask portion 470B comprised substantially of an amorphous carbon material. During an etch process used to pattern semiconductor layer 408, the amorphous carbon material becomes passivated and is thus able to retain its image and dimensionality throughout the entire etch of semiconductor layer 408. Therefore, although pillar hardmask 409 has the desired dimensions for patterning semiconductor layer 408, the material of pillar hardmask 409 may not be suitable to withstand a precise image transfer to a semiconductor layer, i.e. it may degrade during the etch process. Hence, in accordance with an embodiment of the present invention, the image of a pillar hardmask is first transferred to a layer comprising an amorphous carbon material prior to transferring the image to a semiconductor layer, as described in association with FIGS. 4N and 4O. Furthermore, in one embodiment, a protective hardmask layer, i.e. second hardmask layer 406A, is used in between the pillar hardmask and the amorphous carbon layer in order to protect the amorphous carbon layer during fabrication of the pillar hardmask.

Semiconductor layer 408 may be any layer desirable for device fabrication or any other semiconductor structure fabrication requiring a pillar mask. For example, in accordance with an embodiment of the present invention, semiconductor layer 408 comprises any material that can be suitably patterned into an array of distinctly defined semiconductor structures. In one embodiment, semiconductor layer 408 is comprised of a group IV-based material or a III-V material. Additionally, semiconductor layer 408 may comprise any morphology that can suitably be patterned into an array of distinctly defined semiconductor structures. In an embodiment, the morphology of semiconductor layer 408 is selected from the group consisting of amorphous, mono-crystalline and poly-crystalline. In one embodiment, semiconductor layer 408 comprises charge-carrier dopant impurity atoms. Semiconductor layer 408 may further reside above a substrate. The substrate may be comprised of any material suitable to withstand a fabrication process. In an embodiment, the substrate is comprised of a flexible plastic sheet. The substrate may further be comprised of a material suitable to withstand a manufacturing process and upon which semiconductor layers may suitably reside. In an embodiment, the substrate is comprised of group IV-based materials such as crystalline silicon, germanium or silicon/germanium. In another embodiment, the substrate is comprised of a III-V material. The substrate may also comprise an insulating layer. In one embodiment, the insulating layer is comprised of a material selected from the group consisting of silicon oxide, silicon nitride, silicon oxy-nitride and a high-k dielectric layer.

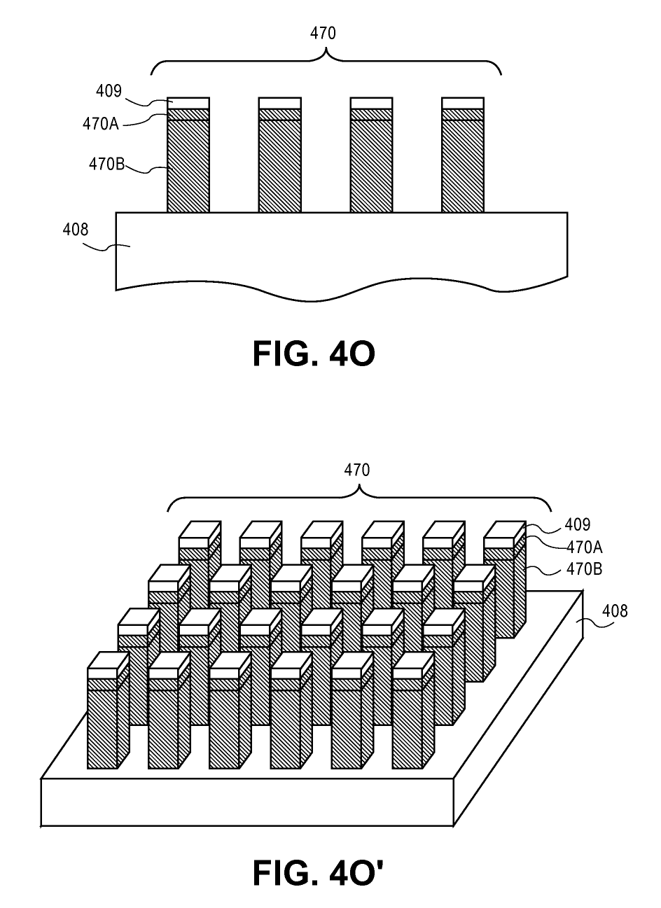

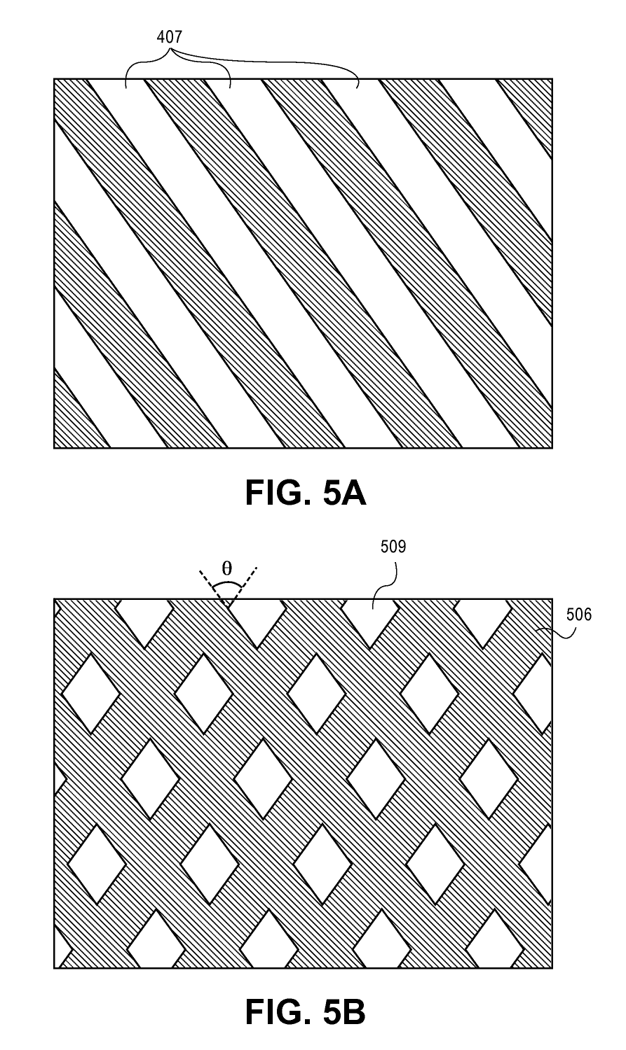

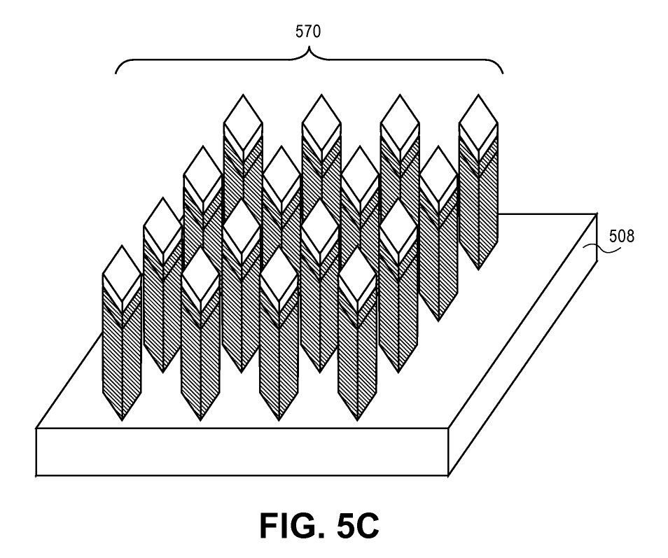

The present invention is not limited to the formation of a pillar mask having square pillars. FIGS. 5A-C illustrate top-down and angle views representing a series of steps in a non-orthogonal self-aligned pillar patterning process using two spacer masks, in accordance with an embodiment of the present invention.

Referring to FIG. 5A, the image from a first spacer mask is transferred to an intermediate hardmask layer to form a patterned intermediate hardmask layer 507. Thus, FIG. 5A corresponds with FIG. 4G′. Referring to FIG. 5B, the image from a second spacer mask is transferred to patterned intermediate hardmask layer 507 to form pillar hardmask 509. Thus, FIG. 5B corresponds to FIG. 4N′. However, in accordance with an alternative embodiment of the present invention, the second spacer mask is formed non-orthogonal to the first spacer mask. In one embodiment, the second spacer mask is formed at an angle θ relative to the first spacer mask, where 0°<θ<90°. In a specific embodiment, the second spacer mask is formed at an angle θ relative to the first spacer mask, where 45°<θ<90°. Thus, pillar hardmask 509 is comprised of a series of diamond-shaped pillars having the angle θ, as depicted in FIG. 5B. The density of the pillars is quadruple the density that would otherwise be achieved using first sacrificial mask 410 in conjunction with second sacrificial mask 440. Referring to FIG. 5C, the image of pillar hardmask 509 having diamond-shaped pillars is transferred to a second mask stack 506 to form etch mask 570 above semiconductor layer 508.

Thus, a method for fabricating a semiconductor mask has been disclosed. In an embodiment, the image of a series of lines from a first spacer mask is first provided to a mask layer to form a patterned mask layer. The image of a series of lines from a second spacer mask is then provided to the patterned mask layer to form a pillar mask comprised of a series of pillars. The image of the series of lines from the second spacer mask is non-parallel with the series of lines from the first spacer mask. In one embodiment, the image of the series of lines from the second spacer mask is orthogonal with the series of lines from the first spacer mask. Thus, each pillar of the pillar mask has a square shape. In an alternative embodiment, the image of the series of lines from the second spacer mask is at an angle θ relative to the series of lines from the first spacer mask, where 45°<θ<90°. Thus, each pillar of the pillar mask has a diamond shape.

What is claimed is:

1. A method for fabricating a semiconductor mask, comprising:
providing the image of a series of lines from a first spacer mask to a mask stack to form a patterned mask stack; and
providing the image of a series of lines from a second spacer mask to said patterned mask stack to form a pillar mask comprised of a series of pillars, wherein the image of said series of lines from said second spacer mask is non-parallel with the image of said series of lines from said first spacer mask.

2. The method of claim 1 wherein the image of said series of lines from said second spacer mask is orthogonal with the image of said series of lines from said first spacer mask, and wherein each pillar of said pillar mask has a square shape.

3. The method of claim 1 wherein the image of said series of lines from said second spacer mask is at an angle θ relative to the image of said series of lines from said first spacer mask, wherein 45°<θ<90°, and wherein each pillar of said pillar mask has a diamond shape.

4. The method of claim 1 wherein said mask stack comprises a layer of amorphous carbon film.

5. A method for fabricating a semiconductor mask, comprising:
providing a semiconductor structure having a first sacrificial mask comprised of a first series of lines above a mask stack;
forming a first spacer mask having spacer lines adjacent to the sidewalls of said first series of lines of said first sacrificial mask;
removing said first sacrificial mask; and, subsequently,
providing the image of the spacer lines from said first spacer mask to said mask stack to form a patterned mask stack;
forming a second sacrificial mask comprised of a second series of lines above said patterned mask stack;
forming a second spacer mask having spacer lines adjacent to the sidewalls of said second series of lines of said second sacrificial mask, wherein the spacer lines of said second spacer mask are non-parallel with the image of the spacer lines from said first spacer mask in said patterned mask stack;
removing said second sacrificial mask; and, subsequently,
providing the image of the spacer lines from said second spacer mask to said patterned mask stack to form a pillar mask stack comprised of a series of pillars.

6. The method of claim 5 wherein the spacer lines of said second spacer mask are orthogonal with the image of the spacer lines from said first spacer mask in said patterned mask layer, and wherein each pillar of said pillar mask stack has a square shape.

7. The method of claim 5 wherein the spacer lines of said second spacer mask are at an angle θ relative to the image of the spacer lines from said first spacer mask in said patterned mask layer, wherein 45°<θ<90°, and wherein each pillar of said pillar mask stack has a diamond shape.

8. The method of claim 5 wherein the frequency of the spacer lines of said first spacer mask is double the frequency of said first series of lines of said first sacrificial mask.

9. The method of claim 8 wherein the pitch of said first series of lines of said first sacrificial mask is approximately 4.

10. The method of claim 9 wherein the frequency of the spacer lines of said second spacer mask is double the frequency of said second series of lines of said second sacrificial mask.

11. The method of claim 10 wherein the pitch of said second series of lines of said second sacrificial mask is approximately 4.

12. The method of claim 5 wherein said mask stack comprises a layer of amorphous carbon film.

13. A method for fabricating a semiconductor mask, comprising:
providing a semiconductor structure having a first sacrificial mask comprised of a first series of lines above a mask stack;
depositing a first spacer layer above said semiconductor structure and conformal with said first sacrificial mask;
etching said first spacer layer to provide a first spacer mask having spacer lines adjacent to the sidewalls of said first series of lines of said first sacrificial mask;
removing said first sacrificial mask; and, subsequently,
providing the image of the spacer lines from said first spacer mask to said mask stack to form a patterned mask stack;
forming a second sacrificial mask comprised of a second series of lines above said patterned mask stack;
depositing a second spacer layer above said patterned mask stack and conformal with said second sacrificial mask;
etching said second spacer layer to provide a second spacer mask having spacer lines adjacent to the sidewalls of said second series of lines of said second sacrificial mask, wherein the spacer lines of said second spacer mask are non-parallel with the image of the spacer lines from said first spacer mask in said patterned mask stack;
removing said second sacrificial mask; and, subsequently,
providing the image of the spacer lines from said second spacer mask to said patterned mask stack to form a pillar mask stack comprised of a series of pillars.

14. The method of claim 13 wherein the spacer lines of said second spacer mask are orthogonal with the image of the spacer lines from said first spacer mask in said patterned mask layer, and wherein each pillar of said pillar mask stack has a square shape.

15. The method of claim 13 wherein the spacer lines of said second spacer mask are at an angle θ relative to the image of the spacer lines from said first spacer mask in said patterned mask layer, wherein 45°<θ<90°, and wherein each pillar of said pillar mask stack has a diamond shape.

16. The method of claim 13 wherein the frequency of the spacer lines of said first spacer mask is double the frequency of said first series of lines of said first sacrificial mask.

17. The method of claim 16 wherein the pitch of said first series of lines of said first sacrificial mask is approximately 4.

18. The method of claim 17 wherein the frequency of the spacer lines of said second spacer mask is double the frequency of said second series of lines of said second sacrificial mask.

19. The method of claim 18 wherein the pitch of said second series of lines of said second sacrificial mask is approximately 4.

20. The method of claim 13 wherein said mask stack comprises a layer of amorphous carbon film.
